(19) United States
(12) Patent Application Publication
(10) Pub. No.: US 2021/0202799 A1
(43) Pub. Date: Jul. 1, 2021

(54) MICRO LIGHT-EMITTING DIODE WITH MAGNET ELECTRODES AND MICRO LIGHT-EMITTING DIODE PANEL

(71) Applicant: HEWLETT-PACKARD DEVELOPMENT COMPANY, L.P., Spring, TX (US)

(72) Inventors: Ning GE, Palo Alto, CA (US); Ya-Ling CHANG, Palo Alto, CA (US); Helen A. HOLDER, Palo Alto, CA (US); Tyler SIMS, Corvallis, OR (US)

(73) Assignee: HEWLETT-PACKARD DEVELOPMENT COMPANY, L.P., Houston, TX (US)

(21) Appl. No.: 16/076,328

(22) PCT Filed: Jul. 18, 2017
(86) PCT No.: PCT/US2017/042668

§ 371 Date: Aug. 8, 2018

(51) Int. Cl. H01L 33/40; H01L 25/075; H01L 33/62; H01L 33/00

(52) U.S. Cl. CPC H01L 33/40; H01L 25/0753; H01L 2933/0016; H01L 33/005; H01L 33/62

(57) ABSTRACT

In some examples, a micro light-emitting diode (μLED) panel may include a μLED including at least two electrodes (or bond pads), and a ferromagnetic material included in the at least two electrodes (or bond pads) and/or disposed on the at least two electrodes (or bond pads). The μLED panel may further include a panel substrate including ferromagnetic material selectively disposed at least at two locations corresponding to locations of the at least two electrodes (or bond pads) to align a plurality of μLEDs including the μLED onto the panel substrate.

### BACKGROUND

A micro light-emitting diode (μLED) may be used to form a display that includes several μLEDs, where each μLED may represent a pixel element of the μLED display. A μLED display may be used with small and relatively low-energy devices such as smartwatches and smartphones.

### BRIEF DESCRIPTION OF DRAWINGS

Features of the present disclosure are illustrated by way of example and not limited in the following figure(s), in which like numerals indicate like elements, in which:

FIG. 1 illustrates an example layout of a micro light-emitting diode (μLED);

FIG. 2A illustrates another example layout of the μLED of FIG. 1;

FIG. 2B illustrates another example layout of the μLED of FIG. 1;

FIG. 3 illustrates an example of a μLED panel (also referred to as μLED display panel);

FIG. 4 illustrates an example of a panel substrate;

FIG. 5 illustrates an example of a μLED display pick and place process; and

FIG. 6 illustrates an example flowchart of a method for forming a μLED panel.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to. The term “based on” means based at least in part on.

A micro light-emitting diode (μLED) with magnet electrodes and μLED panel, and a method for forming a μLED panel are disclosed. The μLED with magnet electrodes may include at least two electrodes (or bond pads as disclosed herein). A ferromagnetic material may be included in the at least two electrodes and/or disposed on the at least two electrodes. For example, with respect to the ferromagnetic material, the at least two electrodes may include a first electrode magnetized into an N pole, and a second electrode magnetized into an S pole (although other combinations may be provided as disclosed herein). A panel substrate of the μLED panel may include ferromagnetic material selectively disposed at least at two locations corresponding to locations of the at least two electrodes to align a plurality of μLEDs including the μLED onto the panel substrate. In this manner, a pick and place device including a plurality of selectively actuated tips may selectively implement a magnetic field on certain ones of the tips to selectively pick a μLED provided on a wafer. Once the μLED on the wafer is picked up, the μLED may be placed onto the panel substrate with the assistance of magnetic alignment between the at least two electrodes of the μLED and the ferromagnetic material selectively disposed at least at the two locations of the panel substrate.

With respect to μLEDs, it is technically challenging to handle the relatively small die size μLED device generally, especially for relatively large transfer processing. In this regard, it is technically challenging to control the μLED die orientation, for example, during manufacture of a μLED panel. It is also technically challenging to achieve μLED pick and place assembly tolerance. For example, because of the relatively small size of μLEDs, it is technically challenging to achieve μLED pick and place assembly tolerance within a specified tolerance range. It is also technically challenging to selectively pick and place μLEDs due to their relatively small size, and proximity to each other on a wafer. Yet further, it is technically challenging to achieve relatively high throughput with respect to the pick and place process for μLED panel manufacture, due to the relatively small size and complexities associated with movement and/or placement of μLEDs onto a panel substrate.

In order to address at least these technical challenges associated with μLEDs, according to examples disclosed herein, a μLED panel may include a μLED including at least two electrodes (or bond pads), and a ferromagnetic material included in the at least two electrodes (or bond pads) and/or disposed on the at least two electrodes (or bond pads). The μLED panel may further include a panel substrate including ferromagnetic material selectively disposed at least at two locations corresponding to locations of the at least two electrodes (or bond pads) to align a plurality of μLEDs including the μLED onto the panel substrate.

According to another example, a method for forming a μLED panel may include generating a magnetic field to actuate a selected tip of a plurality of tips of a μLED display pick and place device. Further, the method may include removably attaching, based on the actuated selected tip, a μLED to the selected tip of the μLED display pick and place device. The μLED may include at least two electrodes or bond pads, and a ferromagnetic material may be included in the at least two electrodes or bond pads, and/or disposed on the at least two electrodes or bond pads. The method may further include aligning, based on magnetic force assistance, the removably attached μLED to a panel substrate. The panel substrate may include ferromagnetic material selectively disposed at least at two locations corresponding to locations of the at least two electrodes or bond pads to align a plurality of μLEDs including the μLED onto the panel substrate.

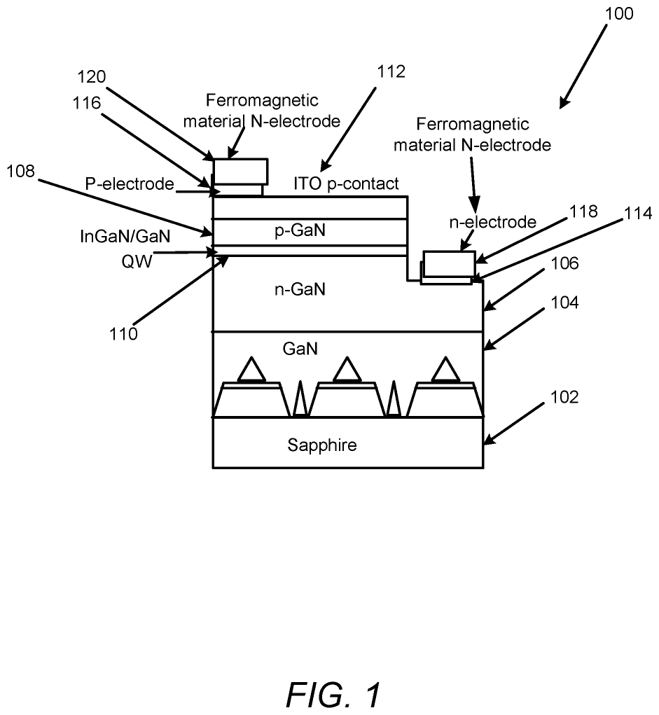

FIG. 1 illustrates an example layout of a μLED 100.

Referring to FIG. 1, the μLED 100 may include a substrate layer 102 formed, for example, of sapphire. The μLED 100 may further include a gallium nitride (GaN) layer 104, an n-GaN layer 106, and a p-GaN layer 108. Here the n- or p-means that the layer is n-type doped or p-type doped respectively. Further, the μLED 100 may include a quantum well layer 110, and an indium tin oxide (ITO) p-contact layer 112. The layers 102-112 are described herein to provide an example of the μLED 100 configuration. However, other layers and/or combinations of layers may be included to implement the μLED 100.

The μLED 100 may include at least two electrodes 114 and 116, as shown in FIG. 1. Alternatively or additionally, the μLED 100 may include at least two bond pads that replace the electrodes 114 and 116, or are included with (e.g., adjacent, on top of, or on bottom of) the electrodes 114 and 116.

The electrodes 114 and 116 may be formed of materials such as aluminum (Al), copper (Cu), titanium (Ti), tungsten (W), gold (Au), or alloys.

For the example of FIG. 1, the electrode 114 may be an n-electrode, and the electrode 116 may be a p-electrode (or vice-versa).

For the example of the electrodes 114 and 116, as shown in FIG. 1, a relatively thin layer of ferromagnetic material may be included in the at least two electrodes (or bond pads) and/or disposed on the at least two electrodes (or bond pads). For example, as shown in FIG. 1, ferromagnetic material 118 may be disposed on the electrode 114, and ferromagnetic material 120 may be disposed on the electrode 116. The ferromagnetic materials 118 and/or 120 may be formed, for example, to include a thickness of a few nanometers, to a few hundred nanometers.

For the example of FIG. 1, the ferromagnetic materials 118 and/or 120 may include iron (Fe), nickel (Ni), cobalt (Co), an alloy, and/or some compounds of rare earth metals. These materials may include ferromagnetism properties, and may further provide conductivity when the ferromagnetic materials 118 and 120 are used with the electrodes 114 and 116.

The ferromagnetic materials 118 and/or 120 may be disposed at other locations of the μLED 100, as opposed to the electrodes (or bond pads) as shown in FIG. 1. For example, the ferromagnetic materials 118 and/or 120 may be disposed at any other location that does not affect the functionality of the μLED 100.

The ferromagnetic materials 118 and/or 120 may be deposited onto the surface of the electrodes (or bond pads), for example, by techniques such as physical vapor deposition (PVD), sputtering, atomic layer deposition (ALD), etc.

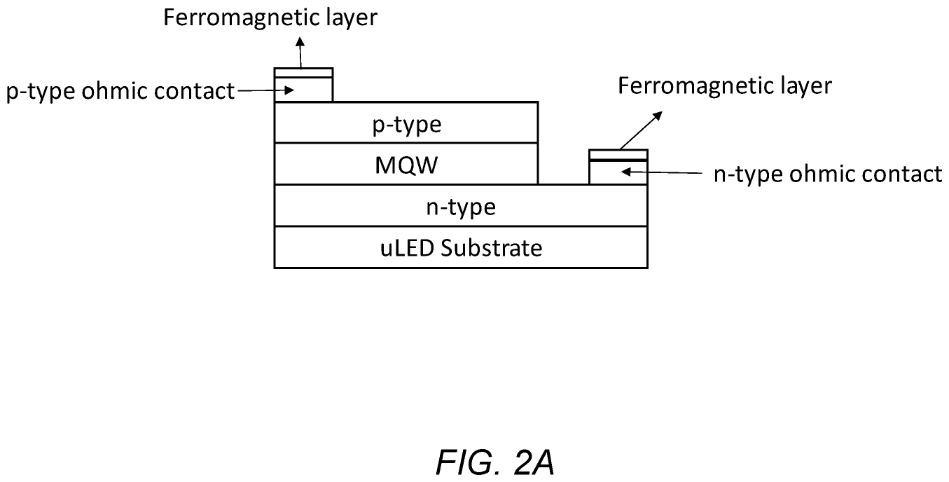

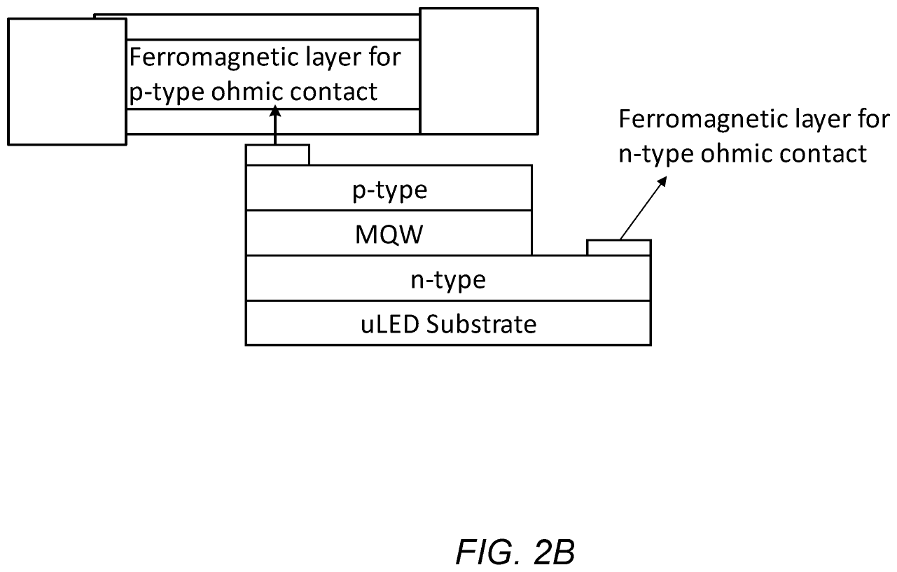

FIG. 2A illustrates another example layout of the μLED of FIG. 1.

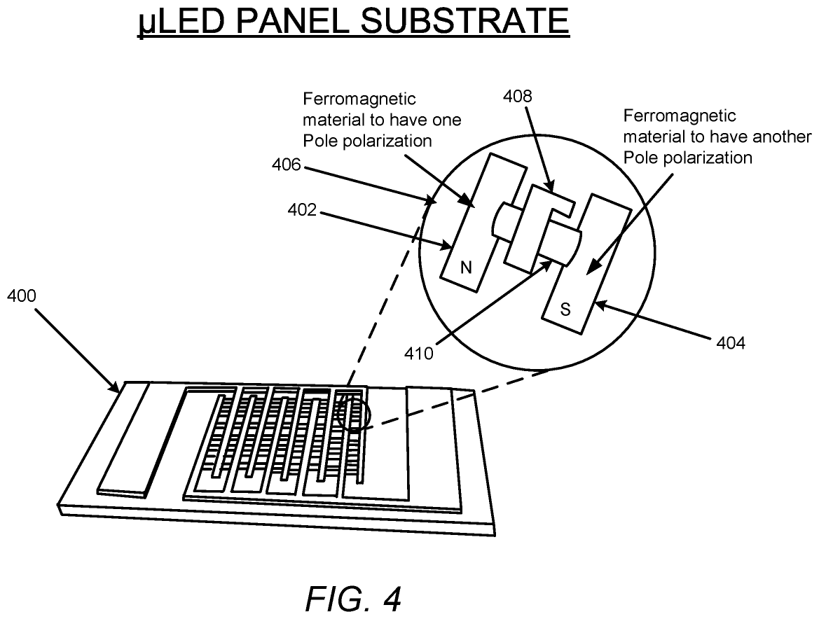

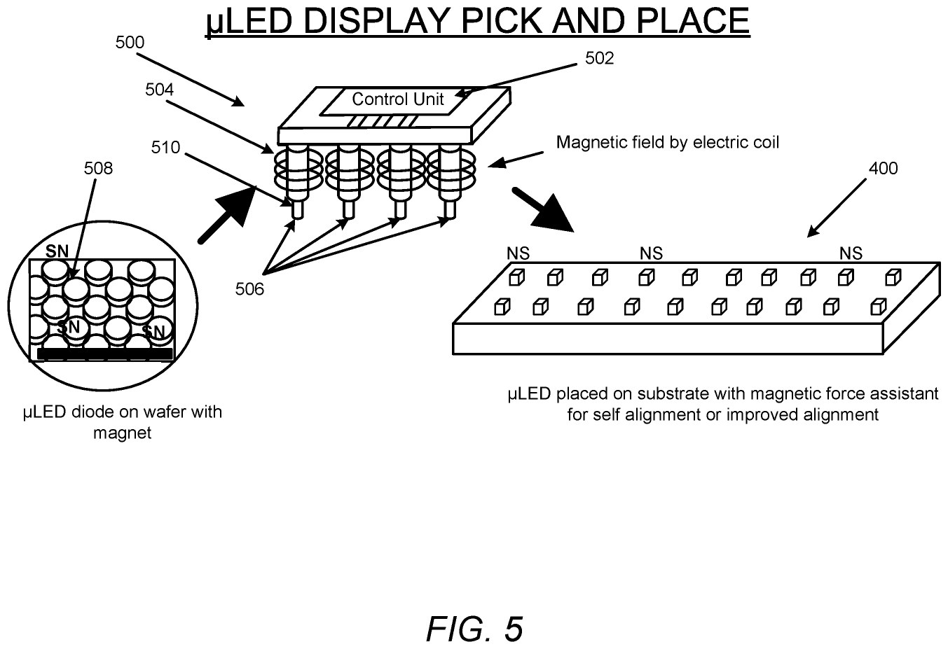

Referring to FIG. 2A, compared to the μLED of FIG. 1, the μLED of FIG. 2A may include a coating of ferromagnetic layer for the μLED pick and place process as described herein with respect to FIGS. 4 and 5.

FIG. 2B illustrates another example layout of the μLED of FIG. 1.

Referring to FIG. 2B, compared to the μLED of FIG. 1, the μLED of FIG. 2B may include the use of ferromagnetic material to replace original material to achieve p-type and n-type ohmic contact for the μLED pick and place process as described herein with respect to FIGS. 4 and 5.

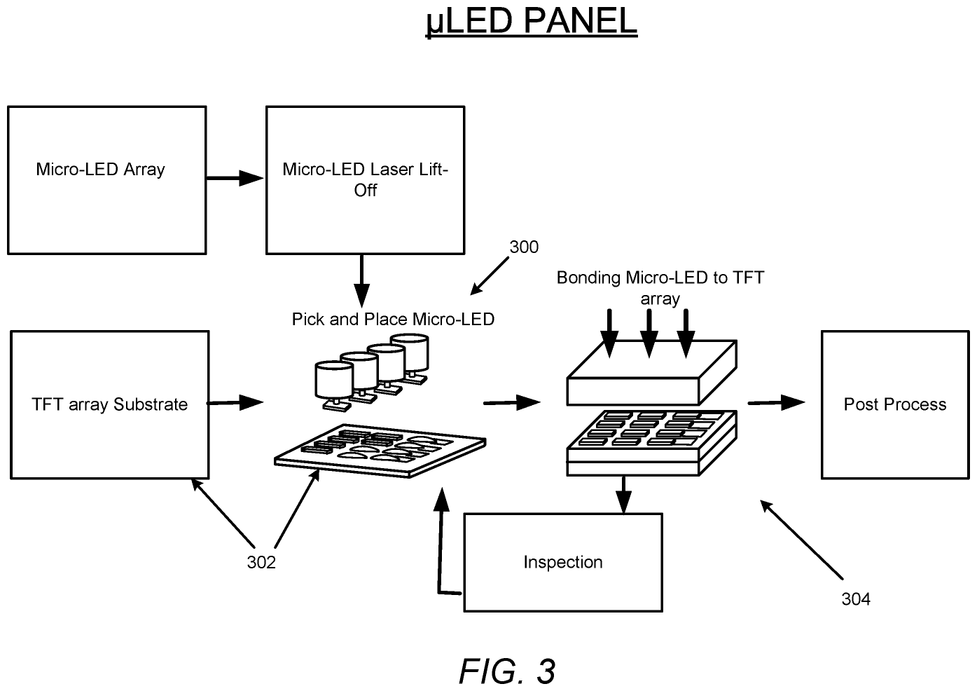

FIG. 3 illustrates an example of a μLED panel (also referred to as μLED display panel).

Referring to FIG. 3, in order to form a μLED panel, a pick and place operation may be performed at 300, where a plurality of μLEDs may be picked (e.g., by grasping) and placed onto a thin-film transistor (TFT) array substrate 302. At 304, the μLEDs placed onto the TFT array substrate 302 may be bonded. The bonded μLEDs may be subject to further post processing and/or inspection.

With respect to the pick and play operation of FIG. 3, such an operation may be subject to various technically challenges such as handling of the relatively small μLEDs, achieving μLED pick and place assembly tolerance, selective picking and placing of μLEDs, and/or achieving relatively high throughput. In this regard, FIG. 4 illustrates an example of a panel substrate 400 that addresses at least these technical challenges.

Referring to FIG. 4, the panel substrate 400, which replaces the TFT array substrate 302, may include ferromagnetic material selectively disposed at least at two locations corresponding to locations of the at least two electrodes 114 and 116 to align a plurality of μLEDs including the μLED 100 onto the panel substrate 400. For example, as shown at 402 and 404, which represent an enlarged view of two locations corresponding to locations of the electrodes 114 and 116, the panel substrate 400 may include ferromagnetic material selectively disposed at 402 and 404. The two locations 402 and 404 of the panel substrate 400 may represent TFT electrodes. The panel substrate 400 may include ferromagnetic material selectively disposed at other locations corresponding to electrodes of other μLEDs. The TFT field-effect transistor (FET) at 406 may further include a gate at 408 and a source at 410.

For the panel substrate 400, the ferromagnetic material may be added to areas such as the TFT electrodes as shown in FIG. 4. The ferromagnetic material may also be implemented in un-functional areas for the north (N) and south (S) poles magnets. For example, the un-functional areas may represent areas where greater than ninety percent of the pixel area of the panel substrate 400 is empty.

The TFT electrodes (e.g., at 402 and 404) may be magnetized into different poles (N and S respectively), which may be performed through different ferromagnetic material components, and/or controlled magnetization processes.

According to an example, the ferromagnetic material for the TFT electrodes (e.g., at 402 and 404) may include iron (Fe), nickel (Ni), cobalt (Co), and/or an alloy.

Referring to FIGS. 1 and 4, according to an example, the ferromagnetic material included in the at least two electrodes 114 and 116, and/or disposed on the at least two electrodes 114 and 116, may include N polarization without any S polarization, and the ferromagnetic material of the panel substrate 400 may include S polarization without any N polarization. In this regard, a plurality of μLEDs such as the μLED 100, each including electrodes with N polarization, may be magnetically aligned and attached to corresponding TFT electrodes of the panel substrate 400. This configuration may facilitate manufacturing of the μLEDs to include N polarization without any S polarization, and the panel substrate 400 to include S polarization without any N polarization.

Referring to FIGS. 1 and 4, according to an example, the ferromagnetic material included in the at least two electrodes 114 and 116, and/or disposed on the at least two electrodes 114 and 116, may include S polarization without any N polarization, and the ferromagnetic material of the panel substrate 400 may include N polarization without any S polarization. In this regard, a plurality of μLEDs such as the μLED 100, each including electrodes with S polarization, may be magnetically aligned and attached to corresponding TFT electrodes of the panel substrate 400. This configuration may similarly facilitate manufacturing of the μLEDs to include N polarization without any S polarization, and the panel substrate 400 to include S polarization without any N polarization.

Referring to FIGS. 1 and 4, according to an example, the ferromagnetic material included in the at least two electrodes 114 and 116, and/or disposed on the at least two electrodes 114 and 116, may include N and S polarizations, and the ferromagnetic material of the panel substrate 400 may include opposite S and N polarizations (as shown in FIGS. 1 and 4). In this regard, a plurality of μLEDs such as the μLED 100, each including electrodes with N and S polarizations, may be magnetically aligned and attached to corresponding TFT electrodes of the panel substrate 400.

Referring to FIGS. 1 and 4, according to an example, the ferromagnetic material included in the at least two electrodes 114 and 116, and/or disposed on the at least two electrodes 114 and 116 may include a greater number of N polarizations compared to S polarizations, or a greater number of S polarizations compared to N polarizations, and the ferromagnetic material of the panel substrate 400 may include a greater number of S polarizations compared to N polarizations, or a greater number of N polarizations compared to S polarizations. This configuration may also facilitate manufacturing of the μLEDs to include a greater number of N or S polarizations compared to S or N polarizations, and the panel substrate 400 to include a greater number of S or N polarizations compared to N or S polarizations.

FIG. 5 illustrates an example of a μLED display pick and place process.

Referring to FIG. 5, with respect to forming of a μLED panel, such as the μLED panel shown at 304 of FIG. 3, a μLED display pick and place device 500 may be used to selectively pick and place μLEDs such as the μLED 100. The μLED display pick and place device 500 may include a control unit 502 to control actuation of electric coils 504 to generate a magnetic field to actuate a selected tip of a plurality of tips 506.

In order to form the μLED panel, the μLED display pick and place device 500 may be actuated to removably attach, based on the actuated selected tip, a μLED to the selected tip. For example, assuming that the μLED 508 is to be picked, the μLED display pick and place device 500 may be actuated to removably attach, based on the actuated selected tip 510, the μLED 508 to the selected tip. Similarly, a plurality of tips may be actuated to pick a plurality of μLEDs. In this manner, a single μLED or a plurality of μLEDs may be picked by the μLED display pick and place device 500.

Once the desired μLED (or μLEDs) is picked, the μLED display pick and place device 500 may be moved (e.g., by transitioning) over the surface of the panel substrate 400. When the picked μLED is brought closer to the panel substrate 400, the picked μLED may be aligned, based on magnetic force assistance, to the panel substrate 400. For example, assuming that the μLED includes electrodes 114 and 116 including N/S polarization, and the panel substrate 400 includes TFT electrodes including S/N polarization, the electrodes 114 and 116 of the μLED may be magnetically attracted to the TFT electrodes of the panel substrate 400 to magnetically align the μLED to the panel substrate 400 to form the μLED panel. That is, the μLED (e.g., the μLED 508) may be self-aligned with the panel substrate 400, without the need for any further alignment capabilities associated with the μLED display pick and place device 500.

Based on the foregoing, the μLED panel and the method for forming the μLED panel as disclosed herein provide a relatively clean process of μLED panel manufacture without the use of chemicals. The μLED panel and the method for forming the μLED panel as disclosed herein provide a high degree of orientation and precision control of alignment of a μLED to the panel substrate. Once the μLED panel is formed, the magnetic properties of the ferromagnetic material may be maintained, without impact to the μLED functionality. The magnetic properties may also be removed, if needed, for example, by using heated temperatures to degauss the ferromagnetic material.

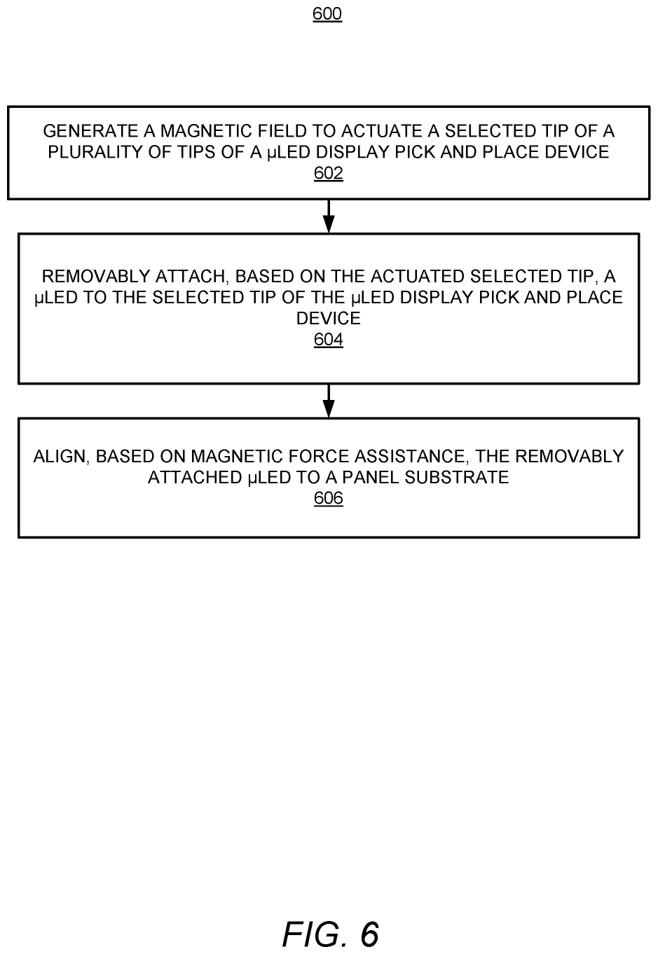

FIG. 6 illustrates an example flowchart of a method 600 for forming a μLED panel.

Referring to FIGS. 1-6, and particularly FIG. 6, for the method 600, at block 602, the method may include generating a magnetic field to actuate a selected tip (e.g., see discussion with respect to FIG. 5) of a plurality of tips of a μLED display pick and place device 500.

At block 604 the method may include removably attaching, based on the actuated selected tip, a μLED (e.g., the μLED 100, or the μLED 508 of FIG. 5) to the selected tip of the μLED display pick and place device 500. The μLED may include at least two electrodes or bond pads, and a ferromagnetic material being at least one of included in the at least two electrodes (e.g., the electrodes 114 and 116) or bond pads, and disposed on the at least two electrodes or bond pads

At block 606 the method may include aligning, based on magnetic force assistance, the removably attached μLED to a panel substrate (e.g., the panel substrate 400 of FIGS. 4 and 5). The panel substrate may include ferromagnetic material selectively disposed at least at two locations corresponding to locations of the at least two electrodes or bond pads to align a plurality of μLEDs including the μLED onto the panel substrate.

According to an example, the method 600 may further include removing the magnetic field to de-actuate the selected tip, and releasing, based on the de-actuation of the selected tip, the aligned μLED from the selected tip.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A micro light-emitting diode (μLED) panel comprising:
a μLED including at least two electrodes;
a ferromagnetic material being at least one of included in the at least two electrodes and disposed on the at least two electrodes; and
a panel substrate including ferromagnetic material selectively disposed at least at two locations corresponding to locations of the at least two electrodes to align a plurality of μLEDs including the μLED onto the panel substrate.

2. The μLED panel according to claim 1, wherein
the ferromagnetic material being at least one of included in the at least two electrodes and disposed on the at least two electrodes includes at least one of iron (Fe), nickel (Ni), cobalt (Co), and an alloy, and
the ferromagnetic material of the panel substrate includes at least one of Fe, Ni, Co, and an alloy.

3. The μLED panel according to claim 1, wherein the at least two locations of the panel substrate correspond to thin-film transistor (TFT) electrodes.

4. The μLED panel according to claim 1, wherein
the ferromagnetic material being at least one of included in the at least two electrodes and disposed on the at least two electrodes includes north (N) polarization without any south (S) polarization, and
the ferromagnetic material of the panel substrate includes S polarization without any N polarization.

5. The μLED panel according to claim 1, wherein
the ferromagnetic material being at least one of included in the at least two electrodes and disposed on the at least two electrodes includes south (S) polarization without any north (N) polarization, and
the ferromagnetic material of the panel substrate includes north (N) polarization without any S polarization.

6. The μLED panel according to claim 1, wherein
the ferromagnetic material being at least one of included in the at least two electrodes and disposed on the at least two electrodes includes north (N) and south (S) polarizations, and
the ferromagnetic material of the panel substrate includes opposite S and N polarizations with respect to the N and S polarizations of the ferromagnetic material being at least one of included in the at least two electrodes and disposed on the at least two electrodes.

7. The μLED panel according to claim 1, wherein
the ferromagnetic material being at least one of included in the at least two electrodes and disposed on the at least two electrodes includes a greater number of north (N) polarizations compared to south (S) polarizations, or a greater number of S polarizations compared to N polarizations, and
the ferromagnetic material of the panel substrate includes a greater number of S polarizations compared to N polarizations, or a greater number of N polarizations compared to S polarizations.

8. A micro light-emitting diode (μLED) panel comprising:
a μLED including at least two bond pads;
a ferromagnetic material being at least one of included in the at least two bond pads and disposed on the at least two bond pads; and
a panel substrate including ferromagnetic material selectively disposed at least at two locations corresponding to locations of the at least two bond pads to align a plurality of μLEDs including the μLED onto the panel substrate.

9. The μLED panel according to claim 8, wherein
the ferromagnetic material being at least one of included in the at least two bond pads and disposed on the at least two bond pads includes at least one of iron (Fe), nickel (Ni), cobalt (Co), and an alloy, and
the ferromagnetic material of the panel substrate includes at least one of Fe, Ni, Co, and an alloy.

10. The μLED panel according to claim 8, wherein
the ferromagnetic material being at least one of included in the at least two bond pads and disposed on the at least two bond pads includes north (N) polarization without any south (S) polarization, and
the ferromagnetic material of the panel substrate includes S polarization without any N polarization.

11. The μLED panel according to claim 8, wherein
the ferromagnetic material being at least one of included in the at least two bond pads and disposed on the at least two bond pads includes south (S) polarization without any north (N) polarization, and
the ferromagnetic material of the panel substrate includes north (N) polarization without any S polarization.

12. A method for forming a micro light-emitting diode (μLED) panel comprising:
generating a magnetic field to actuate a selected tip of a plurality of tips of a μLED display pick and place device;
removably attaching, based on the actuated selected tip, a μLED to the selected tip of the μLED display pick and place device, wherein the μLED includes
at least two electrodes or bond pads, and
a ferromagnetic material being at least one of included in the at least two electrodes or bond pads, and disposed on the at least two electrodes or bond pads; and
aligning, based on magnetic force assistance, the removably attached μLED to a panel substrate, wherein the panel substrate includes ferromagnetic material selectively disposed at least at two locations corresponding to locations of the at least two electrodes or bond pads to align a plurality of μLEDs including the μLED onto the panel substrate.

13. The method according to claim 12, further comprising:
removing the magnetic field to de-actuate the selected tip; and
releasing, based on the de-actuation of the selected tip, the aligned μLED from the selected tip.

14. The method according to claim 12, further comprising:
polarizing the ferromagnetic material being at least one of included in the at least two electrodes or bond pads, and disposed on the at least two electrodes or bond pads to include north (N) polarization without any south (S) polarization; and
polarizing the ferromagnetic material of the panel substrate to include S polarization without any N polarization.

15. The method according to claim 12, further comprising:
polarizing the ferromagnetic material being at least one of included in the at least two electrodes or bond pads, and disposed on the at least two electrodes or bond pads to include south (S) polarization without any north (N) polarization; and
polarizing the ferromagnetic material of the panel substrate to include N polarization without any S polarization.
